(19) United States
(12) Patent Application Publication
(10) Pub. No.: US 2021/0035939 A1
(43) Pub. Date: Feb. 4, 2021

(54) PACKAGE STRUCTURE

(71) Applicant: POWERTECH TECHNOLOGY INC., HSINCHU COUNTY (TW)

(72) Inventor: Ting-Feng Su, HSINCHU COUNTY (TW)

(21) Appl. No.: 16/653,948

(22) Filed: Oct. 15, 2019

(30) Foreign Application Priority Data
Jul. 31, 2019 (TW) 108127113

(51) Int. Cl. H01L 23/00; H01L 23/498; H01L 23/13; H01L 23/31

(52) U.S. Cl. CPC H01L 24/24; H01L 23/49816; H01L 23/13; H01L 2224/24225; H01L 23/49838; H01L 23/49833; H01L 23/49822; H01L 23/3185

(57) ABSTRACT

A package structure includes a redistribution layer having an upper surface and a lower surface opposite to each other, in which the redistribution layer has at least one recess on its lower surface, an electronic element disposed on the upper surface of the redistribution layer, at least one first conductive ball disposed on the at least one recess of the redistribution layer, in which a portion of the at least one first conductive ball is filled into the at least one recess, and a plurality of second conductive balls disposed on the lower surface of the redistribution layer. The height of the first conductive ball is larger than the height of each of the second conductive balls in a direction perpendicular to the lower surface of the redistribution layer.

### BACKGROUND OF THE INVENTION

### 1. Field of the Invention

The present invention relates to a package structure, more particularly to a package structure having a recess disposed on the redistribution layer thereof.

### 2. Description of the Prior Art

Fan out wafer level packaging (FOWLP) and fan out panel level packaging (FOPLP) are widely used in package structures to reduce production cost because of the advantages such as improving ability of the device, increasing input/output density and reducing the thickness of the package. However, when the fan out package is on board and a temperature cycling test is performed, a greater stress may be formed in the solder ball near the edge of the chip because of the excessive difference between the coefficient of thermal expansion (CTE) of the circuit board and the CTE of the chip, such that the solder ball may be easily broken. Thus, to reduce the stress of the solder balls and to improve the reliability of the product is an important issue.

### SUMMARY OF THE INVENTION

One of the purposes of the present invention is to provide a package structure, and the surface of the redistribution layer of the package structure has a plurality of recesses disposed thereon, such that the conductive balls disposed in the recesses have greater height, and the possibility of damage of these conductive balls can be reduced.

According to some embodiments, the present invention provides a package structure. The package structure includes a redistribution layer having an upper surface and a lower surface opposite to each other, wherein the lower surface of the redistribution layer has at least one first recess, an electronic element disposed on the upper surface of the redistribution layer, at least one first conductive ball disposed on the at least one first recess of the redistribution layer, wherein a portion of the at least one first conductive ball is filled into the at least one first recess, and a plurality of second conductive balls disposed on the lower surface of the redistribution layer. In a direction perpendicular to the lower surface of the redistribution layer, a height of the at least one first conductive ball is larger than a height of each of the second conductive balls.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically illustrates a cross-sectional view of a package structure according to a first embodiment of the present invention.

FIG. 2 schematically illustrates a bottom view of a lower surface of the distribution layer according to the first embodiment of the present invention.

FIG. 3 schematically illustrates a bottom view of a lower surface of the distribution layer according to a variant embodiment of the first embodiment of the present invention.

FIG. 4 schematically illustrates a cross-sectional view of a package structure according to another variant embodiment of the first embodiment of the present invention.

FIG. 5 schematically illustrates a cross-sectional view of a package structure according to a second embodiment of the present invention.

FIG. 6 schematically illustrates a bottom view of a lower surface of the distribution layer according to the second embodiment of the present invention.

FIG. 7 schematically illustrates a bottom view of a lower surface of the distribution layer according to a variant embodiment of the second embodiment of the present invention.

FIG. 8 schematically illustrates a cross-sectional view of a package structure according to a third embodiment of the present invention.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the display device, and certain elements in various drawings may not be drawn to scale. In addition, the number and dimension of each device shown in drawings are only illustrative and are not intended to limit the scope of the present disclosure.

It will be understood that when an element or layer is referred to as being “on” or “connected to” another element or layer, it can be directly on or directly connected to the other element or layer, or intervening elements or layers may be presented. In contrast, when an element is referred to as being “directly on” or “directly connected to” another element or layer, there are no intervening elements or layers presented.

It should be noted that the technical features in different embodiments described in the following can be replaced, recombined, or mixed with one another to constitute another embodiment without departing from the spirit of the present disclosure.

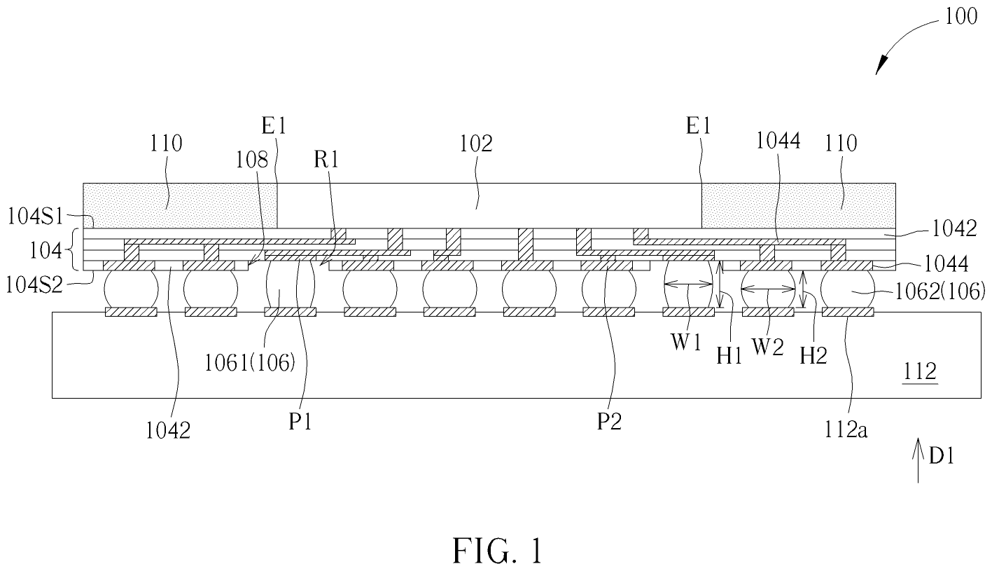

FIG. 1 schematically illustrates a cross-sectional view of a package structure according to a first embodiment of the present invention. According to this embodiment, the package structure 100 may for example be a fan out wafer level packaging (FOWLP) structure or a fan out panel level packaging (FOPLP) structure, but not limited thereto. As shown in FIG. 1, the package structure 100 may for example include an electronic element 102, a redistribution layer 104 and a plurality of conductive balls 106. The redistribution layer 104 includes an upper surface 104S1 and a lower surface 104S2 opposite to each other. The redistribution layer 104 may for example include a stacking structure formed of a plurality of insulating layers 1042 and a plurality of conductive layers 1044, wherein the insulating layers 1042 may for example include silicon dioxide (SiO₂), silicon nitride (SiN), silicon oxynitride (SiON), tantalum pentoxide (Ta₂O₅), aluminum oxide (Al₂O₃) or other suitable insulating materials, and the conductive layers 1044 may for example include aluminum, copper, tin, nickel, gold, silver, other suitable conductive materials or any combination thereof. It should be noted that the composition of the redistribution layer 104, the material of the insulating layer 1042, and the material of the conductive layer 1044 are not limited to the above-mentioned content. The electronic element 102 is disposed on the upper surface 104S1 of the redistribution layer 104 and may for example include semiconductor chip, but not limited thereto. The conductive balls 106 are disposed on the lower surface 104S2 of the redistribution layer 104 and may for example include copper, tin, nickel, gold, lead or other suitable conductive materials, but not limited thereto. In this embodiment, the lower surface 104S2 of the redistribution layer 104 has a first recess R1, wherein the first recess R1 may be formed by removing a portion of the redistribution layer 104. For example, an opening 108 may be formed in the insulating layer 1042 adjacent to the lower surface 104S2 to expose a conductive layer 1044, and the first recess R1 may be formed of the opening 108 and the exposed conductive layer 1044, but not limited thereto. It should be noted that although the opening 108 shown in FIG. 1 penetrates only one insulating layer 1042, the present invention is not limited thereto. In some embodiments, the opening 108 may penetrate a single layer or multiple layers of the insulating layer 1042. Furthermore, another conductive layer 1044 which is not the closest to the lower surface 104S2 may include at least one bonding pad P1 exposed by the opening 108, and the conductive layer 1044 which is the closest to the lower surface 104S2 may include a plurality of bonding pads P2. In this embodiment, the conductive balls 106 which are disposed on the first recess R1 of the redistribution layer 104 may be defined as the first conductive balls 1061, and the conductive balls 106 which are disposed on the lower surface 104S2 of the redistribution layer may be defined as the second conductive balls 1062. That is, the first conductive balls 1061 are disposed on the first recess R1, and a portion of the first conductive ball 1061 can be filled into the first recess R1 to be electrically connected to the bonding pad P1; and the second conductive balls 1062 are disposed on the lower surface 104S2 which does not include the first recess R1 to be electrically connected to the corresponding bonding pads P2, but not limited thereto. According to this embodiment, because the first conductive balls 1061 are disposed on the first recess R1, and a portion of the first conductive ball 106 may be filled into the first recess R1, the height H1 of the first conductive balls 1061 located on the first recess R1 is greater than the height H2 of the second conductive balls 1062 located on the lower surface 104S2 of the redistribution layer 104 in a direction D1, wherein the direction D1 may for example perpendicular to the lower surface 104S2 of the redistribution layer 104. Besides, the width W1 of the first conductive balls 1061 located on the first recess R1 is less than the width W2 of the second conductive balls 1062 located on the lower surface 104S2 of the redistribution layer 104 (that is, the first conductive balls 1061 are thinner than the second conductive balls 1062) in some embodiments, wherein the width W1 and the width W2 may for example be the maximum width of the first conductive balls 1061 and the second conductive balls 1062 respectively, but not limited thereto.

As shown in FIG. 1, the package structure 100 may further include an encapsulation layer 110 disposed on the upper surface 104S1 of the redistribution layer 104. The encapsulation layer 110 may for example include composite material formed of epoxy resin, ceramic powder and carbon black or epoxy molding compound (EMC), but not limited thereto. The encapsulation layer 110 is disposed on the upper surface 104S1 of the redistribution layer 104 and encloses the electronic element 102. It should be noted that although the electronic element 102 is not covered by the encapsulation layer 110, the present invention is not limited thereto. The encapsulation layer 110 may cover the electronic element 102 in other embodiments, that is, the electronic element 102 is disposed between the encapsulation layer 110 and the redistribution layer 104.

In some embodiments, the package structure 100 may further include a circuit board 112 located below the conductive balls 106. That is, the first conductive balls 1061 and the second conductive balls 1062 are disposed between the redistribution layer 104 and the circuit board 112, but not limited thereto. The circuit board 112 may for example include rigid printed circuit board (PCB) which includes single layer PCB, double layer PCB or multi-layer PCB, but not limited thereto. For example, a plurality of conductive pads 112a may be disposed on the upper surface of the circuit board 112, and the conductive pads 112a are respectively in contact with the conductive balls 106, so as to be electrically connected to the electronic element 102 through the bonding pads P1, P2 and the redistribution layer 104.

As shown in FIG. 1, the first recess R1 may be disposed on the edge E1 of the electronic element 102. Specifically, the first recess R1 may be overlapped with the edge E1 of the electronic element 102 in the direction D1, but not limited thereto. In some embodiments, the first recess R1 may be adjacent to the edge E1 of the electronic element 102, and is not overlapped with the edge E1 in the direction D1. For example, the first recess R1 may be adjacent to the edge E1 in the direction D1, and is overlapped with the electronic element 102. Alternatively, the first recess R1 is adjacent to the edge E1 in the direction D1, and is overlapped with the encapsulation layer 110. Therefore, the conductive balls 1061 disposed on the first recess R1 may be adjacent to the edge E1 in the direction D1, and may be overlapped with the edge E1 or not, but not limited thereto.

It is noted worthy that because the coefficient of thermal expansion (CTE) of the electronic element 102 and the CTE of the circuit board 112 are different, when a temperature cycling test is performed for the package structure 100, the stress of the conductive balls 106 which are located between the electronic element 102 and the circuit board 112 would increase, especially, the conductive balls 106 which are adjacent to the edge E1 of the electronic element 102 may be easily damaged due to stress, thereby decreasing the stability of the package structure 100. In this embodiment, because the package structure 100 has first recess R1, the conductive balls 106 (for example the first conductive ball 1061 shown in FIG. 1) adjacent to the edge E1 of the electronic element 102 may have greater height and/or smaller width to tolerate greater stress, such that the stress produced during the temperature cycling test can be reduced, and the possibility of damage of the conductive balls 106 can thereby be reduced. Thus, the stability of the package structure 100 can be improved.

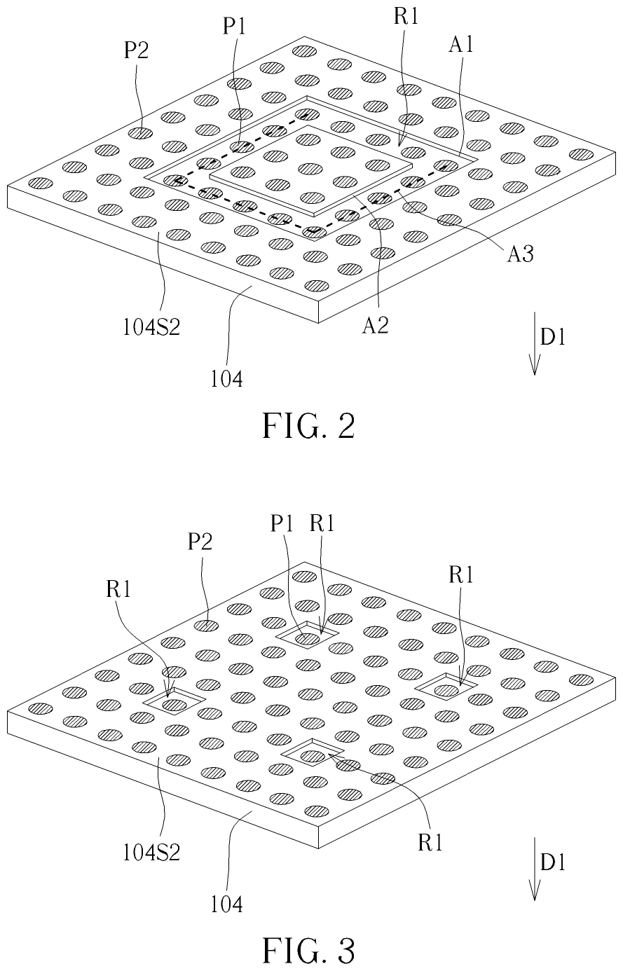

FIG. 2 schematically illustrates a bottom view of a lower surface of the distribution layer according to the first embodiment of the present invention. As shown in FIG. 2, the lower surface 104S2 of the redistribution layer 104 has exposed bonding pads P1, P2 and first recess R1. The exposed bonding pads P1, P2 may for example be used to dispose conductive balls (not shown in FIG. 2), and the exposed bonding pads P1, P2 may for example be electrically connected to the circuit board (not shown in FIG. 2) through the conductive balls, but not limited thereto. According to this embodiment, the first recess R1 may be disposed along the edge E1 (not shown in FIG. 2) of the electronic element 102, that is, the first recess R1 in this embodiment has a square frame shape. It should be noted that the projection of the edge E1 on the lower surface 104S2 may be projection A1, projection A2 or projection A3 in the direction D1, and the present invention is not limited thereto. For example, when the projection of the edge E1 on the lower surface 104S2 is projection A1, the electronic element 102 may be disposed in the region of the projection A1, the first recess R1 may be disposed adjacent to the edge E1 in the direction D1, and the first recess R1 may be overlapped with the electronic element 102; when the projection of the edge E1 on the lower surface 104S2 is projection A3, the electronic element 102 may be disposed in the region of the projection A3, the first recess R1 may be disposed adjacent to the edge E1 in the direction D1, and the first recess R1 may be overlapped with the encapsulation layer 110 (not shown in FIG. 2); when the projection of the edge E1 on the lower surface 104S2 is projection A2, the electronic element 102 may be disposed in the region of the projection A2, the first recess R1 may be disposed adjacent to the edge E1 in the direction D1, a portion of the first recess R1 may be overlapped with the electronic element 102, and another portion of the first recess R1 may be overlapped with the encapsulation layer 110.

FIG. 3 schematically illustrates a bottom view of a lower surface of the distribution layer according to a variant embodiment of the first embodiment of the present invention. As shown in FIG. 3, the main difference between this variant embodiment and the first embodiment is that the first recess R1 is not disposed along the edge of the electronic element in this variant embodiment. According to this variant embodiment, because the stress produced through the difference between the CTEs of the electronic element and the circuit board is greater at the corner of the electronic element, the package structure 100 may include a plurality of first recesses R1, and each of the first recesses R1 may be disposed at the corresponding corner of the electronic element 102 in the direction D1. For example, as shown in FIG. 3, the lower surface 104S2 of the redistribution layer 104 may include four first recesses R, and the four first recesses R1 may be disposed on four corresponding corners of the lower surface 104S2 respectively. Four first conductive balls (the first conductive balls 1061 shown in FIG. 1) may be disposed in the four first recesses R1 respectively, and the second conductive balls (the second conductive balls 1062 shown in FIG. 1) may be disposed in other portions of the lower surface 104S2 which does not include a first recess. The height of the first conductive balls is greater than the height of the second conductive balls. The first recesses R1 in this variant embodiment may be overlapped with the electronic element or not in the direction D1. It should be noted that the number of the first recesses R1 shown in FIG. 3 and the number of the first conductive balls disposed in the first recess R1 mentioned above are only exemplary, and the present invention is not limited thereto. In other embodiments, the package structure 100 may include greater or less number of the first recess R1.

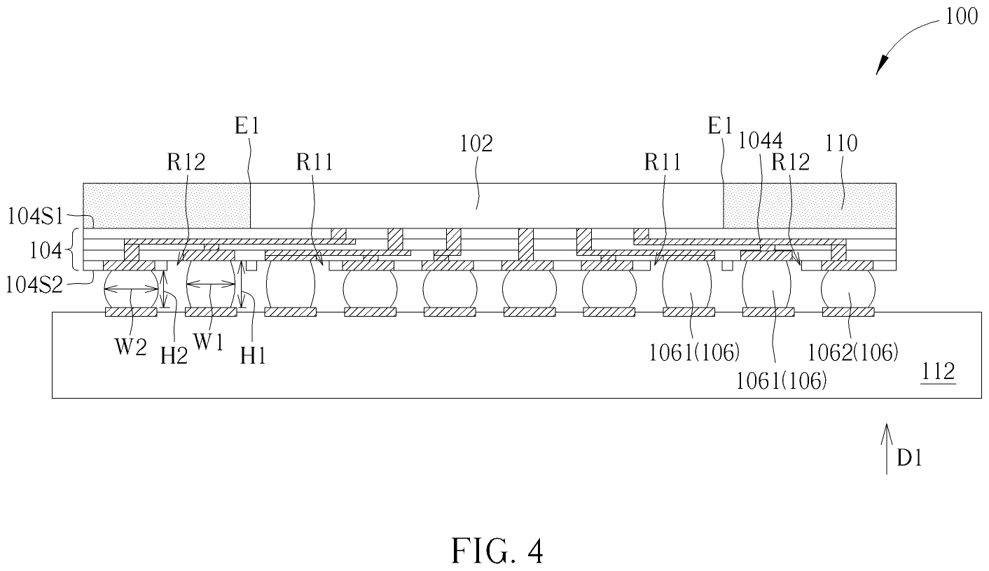

FIG. 4 schematically illustrates a cross-sectional view of a package structure according to another variant embodiment of the first embodiment of the present invention. As shown in FIG. 4, the main difference between this variant embodiment and the first embodiment is that the package structure 100 includes two first recesses R11 and R12 in this variant embodiment, wherein the first recesses R11 and R12 are disposed along the edge E1 of the electronic element 102 in the direction D1. That is, the first recesses R11 and R12 are adjacent to the edge E1 in the direction D1. For example, as shown in FIG. 4, the first recess R11 may be adjacent to the edge E1 and overlapped with the electronic element 102 in the direction D1, and the first recess R12 may be adjacent to the edge E1 and overlapped with the encapsulation layer 110 in the direction D1. Besides, the first conductive balls 1061 may be disposed in the first recesses R11 and R12, and the second conductive balls 1062 may be disposed in other portion of the lower surface 104S2 without the first recesses R11 and R12, wherein the height H1 of the first conductive balls 1061 in the direction D1 is greater than the height H2 of the second conductive balls 1062 in the direction D1. Besides, in some embodiments, the width W1 of the first conductive balls 1061 is less than the width W2 of the second conductive balls 1062, but not limited thereto. It should be noted that the structure shown in FIG. 4 and the example mentioned above is only an example of this variant embodiment, and the present invention is not limited thereto. For example, the package structure 100 in this variant embodiment may include a greater number of first recesses disposed along the edge E1, and the first recesses R11 and R12 may be overlapped with the edge E1 or not in the direction D1. Optionally, the first recesses R11 and R12 may be disposed correspondingly to the corners of the electronic element 102 but not disposed along the edge E1, but not limited thereto.

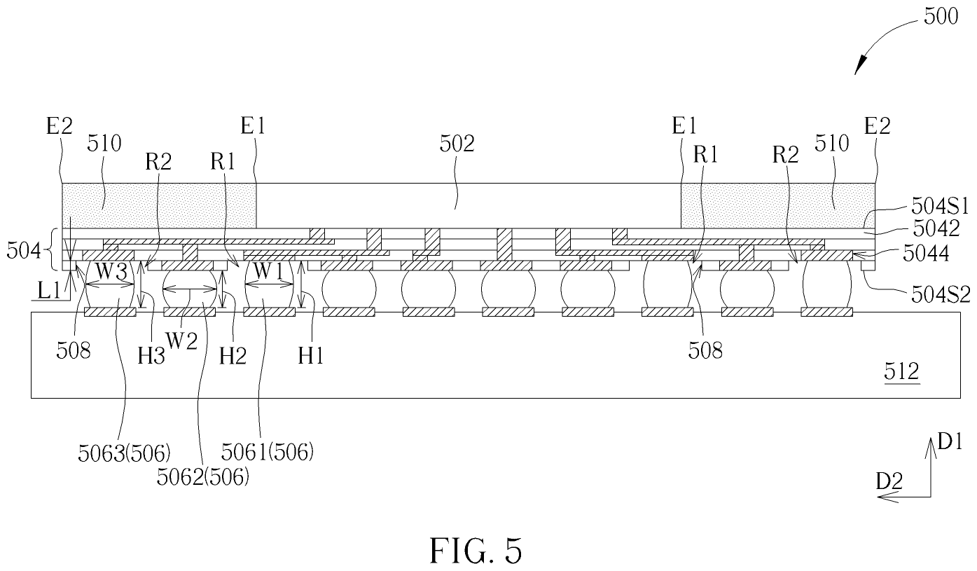

FIG. 5 schematically illustrates a cross-sectional view of a package structure according to a second embodiment of the present invention. As shown in FIG. 5, the main difference between this embodiment and the first embodiment is that the package structure 500 in this embodiment further includes a second recess R2 located on the lower surface 504S2 of the redistribution layer 504, wherein the second recess R2 is overlapped with the encapsulation layer 510 in the direction D1. The material and disposed position of the redistribution layer 504, the electronic element 502, the encapsulation layer 510 and the circuit board 512 in the package structure 500 may be the same as the first embodiment, and will not be redundantly described here. According to this embodiment, the package structure 500 may include first recess R1 and second recess R2, wherein the formation method and disposition of the first recess R1 are the same as the first embodiment, and will not be redundantly described here. The second recess R2 may be disposed on the lower surface 504S2 of the redistribution layer 504 correspondingly to the edge E2 of the encapsulation layer 510. Specifically, the conductive ball 506 disposed in the second recess R2 may be the conductive ball which is the closest to the edge E2 in a direction D2. That is, the conductive ball 506 disposed in the second recess R2 may be the outermost conductive ball 506 of the package structure 500, but not limited thereto. The second recess R2 can be formed of an opening 508 formed by removing single layer or multiple layers of insulating layer 5042 and the conductive layer 5044, which is the same as the formation method of the first recess R1. Besides, the conductive balls 506 disposed in the first recess R1 can be defined as first conductive balls 5061, the conductive balls 506 disposed in the second recess R2 can be defined as third conductive balls 5063, and the conductive balls 506 disposed on the lower surface 504S2 of the redistribution layer 504 without the first recess R1 and the second recess R2 can be defined as second conductive balls 5062. Because a portion of the first conductive balls 5061 and a portion of the third conductive balls 5063 may be filled into the first recess R1 and the second recess R2 respectively, the height H1 of the first conductive balls 5061 and the height H3 of the third conductive balls 5063 are greater than the height H2 of the second conductive balls 5062 in the direction D1. Besides, the width W1 of the first conductive balls 5061 and/or the width W3 of the third conductive balls 5063 may be less than the width W2 of the second conductive balls 5062 in some embodiments, but not limited thereto. The openings 508 in the first recess R1 and the second recess R2 may have equal depth L1 (or the thickness of single insulating layer) in this embodiment, but not limited thereto. In some embodiments, the depth of the opening 508 in the first recess R1 may equal to the thickness of two or more layers of the insulating layer 5042, and the depth of the opening 508 in the second recess R2 may equal to the thickness of single insulating layer 5042. That is, the height H1 of the first conductive balls 5061 may be greater than the height H3 of the third conductive balls 5063, but not limited thereto. When the temperature cycling test is performed for the package structure 500, except for the greater stress produced in the conductive balls 506 located at the edge E1 of the electronic element 502, the stress of the conductive balls located between the encapsulation layer 510 and the circuit board 512 may be increased because of the difference between the CTEs of the encapsulation layer 510 and the circuit board 512, especially, the conductive balls located at the edge E2 of the encapsulation layer 510 may be damaged due to stress, thereby reducing the stability of the package structure 500. In this embodiment, because the package structure includes the first recess R1 and the second recess R2, the conductive balls adjacent to the edge E1 of the electronic element 502 (the first conductive balls 5061 shown in FIG. 5) and the conductive balls adjacent to the edge E2 of the encapsulation layer 510 (the third conductive balls 5063 shown in FIG. 5) may have greater height, such that the stress produced during the temperature cycling test can be reduced, and the possibility of damage of the conductive balls 506 can be reduced. Therefore, the stability of the package structure 500 can be improved.

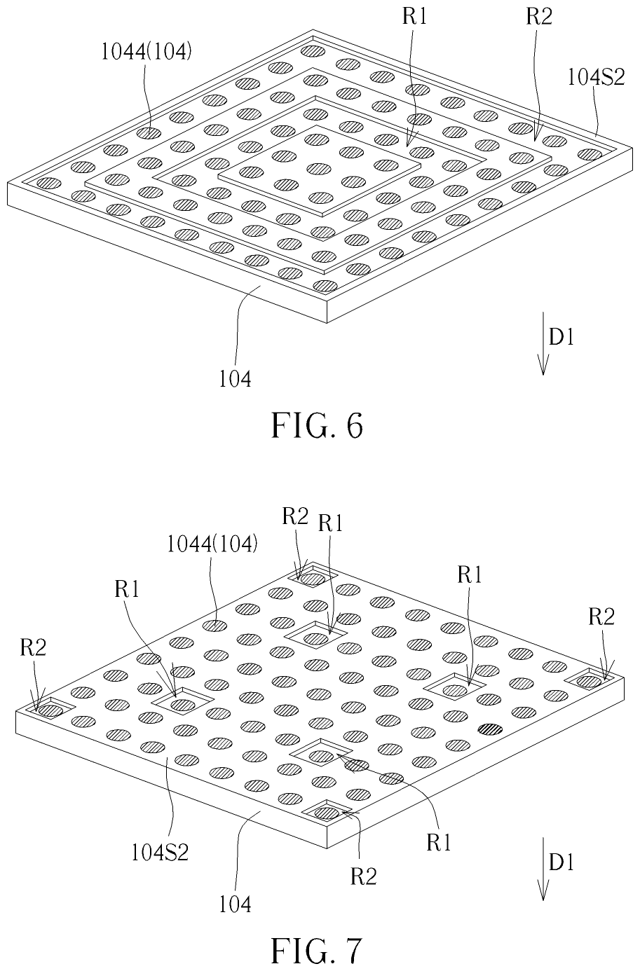

FIG. 6 schematically illustrates a bottom view of a lower surface of the distribution layer according to the second embodiment of the present invention. As shown in FIG. 6, the lower surface 504S2 of the redistribution layer 504 includes the first recess R1 and the second recess R2, wherein the first recess R1 in this embodiment may be the same as the first embodiment, and will not be redundantly described here. In this embodiment, the second recess R2 may be disposed along the edge E2 (shown in FIG. 5) of the encapsulation layer 510, and the second recess R2 may for example have a square frame shape, but not limited thereto. The exposed conductive layer 5044 located in the second recess R2 may be used to dispose the third conductive balls (the third conductive balls 5063 shown in FIG. 5), and the conductive layer 5044 may be electrically connected to the circuit board 512 through the third conductive balls 5063. It should be noted that although only one first recess R1 and one second recess R2 are shown in FIG. 6, the present invention is not limited thereto. For example, the package structure 500 may include greater number of the first recesses R1 or the second recesses R2.

FIG. 7 schematically illustrates a bottom view of a lower surface of the distribution layer according to a variant embodiment of the second embodiment of the present invention. As shown in FIG. 7, the main difference between this variant embodiment and the second embodiment is that the first recess R1 and the second recess R2 are not disposed along the edge E1 of the electronic element 502 and the edge E2 of the encapsulation layer 510 in this variant embodiment. The first recess R1 shown in FIG. 7 may be the same as the first recess R1 shown in FIG. 3, and will not be redundantly described here. In this variant embodiment, the package structure 500 may include a plurality of second recesses R2, and each of the second recesses R2 may be disposed at the corresponding corner of the encapsulation layer 510 respectively in the direction D1. For example, as shown in FIG. 7, the lower surface 504S2 of the redistribution layer 504 may include four second recesses R2, these four second recesses R2 may be disposed on the lower surface 504S2 and correspond to four corners of the encapsulation layer 510, and four third conductive balls 5063 may be disposed in the four second recesses R2, but not limited thereto. In some other embodiments, the number of the second recesses R2 may be different from the number of the second recesses R2 shown in FIG. 7. Besides, the first recesses R1 and the second recesses R2 may not be disposed correspondingly to the corners of the electronic element 502 and the corners of the encapsulation layer 510 respectively at the same time. For example, when the first recesses R1 is disposed correspondingly to the corners of the electronic element 502, the second recess R2 may be disposed along the edge E2 of the encapsulation layer 510. Alternatively, when the first recess R1 is disposed along the edge E1 of the electronic element 502, the second recesses R2 may be disposed correspondingly to the corners of the encapsulation layer 510, but not limited thereto.

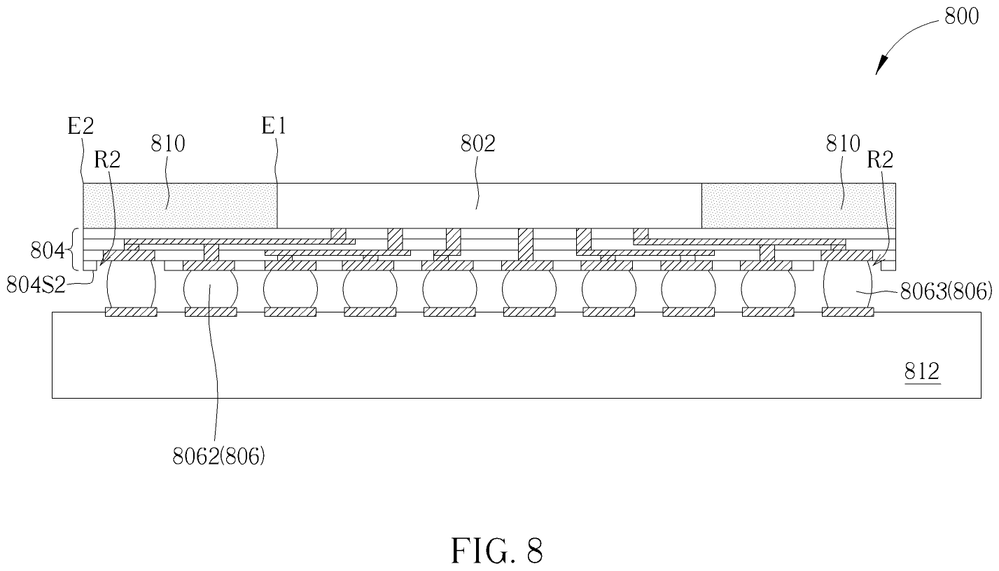

FIG. 8 schematically illustrates a cross-sectional view of a package structure according to a third embodiment of the present invention. The main difference between this embodiment and the first embodiment is that the circuit board 812 and the electronic element 802 of the package structure 800 are semiconductor chips. The material of the redistribution layer 804, the electronic element 802, the conductive balls 806 and the encapsulation layer 810 may be the same as the first embodiment, and will not be redundantly described here. In this embodiment, the lower surface 804S2 of the redistribution layer 804 of the package structure 800 includes the second recess R2, but does not include the first recess R1. Therefore, the conductive balls 806 include the third conductive balls 8063 disposed in the second recess R2 and the second conductive balls 8062 disposed on the lower surface 804S2 without the second recess R2 (that is, the conductive balls 806 in this embodiment do not include the first conductive balls which are disposed in the first recess). The formation method and disposition of the second recess R2 may be the same as the second embodiment, and will not be redundantly described here. Because of the material of the circuit board 812 and the electronic element 802 is a semiconductor chip in this embodiment, when the temperature cycling test is performed for the package structure 800, the CTEs of the circuit board 812 and the electronic element 802 are substantially the same, such that the conductive balls 806 which are adjacent to the edge E1 of the electronic element 802 may not be damaged by the excessive stress. However, because the CTEs of the encapsulation layer 810 and the circuit board 812 are different, the second recess R2 can be disposed to reduce the stress in the conductive balls 806 (that is, the third conductive balls 8063 disposed on the second recess R2) adjacent to the edge E2 of the encapsulation layer 810. The theory of reducing the stress is mentioned above, and will not be redundantly described here.

In summary, a package structure is provided by the present invention. The package structure includes a recess structure located on the lower surface of the redistribution layer, wherein the recess structure can be disposed near the edge of the electronic element or near the edge of the encapsulation layer. Besides, the recess structure may be optionally disposed along the edge of the electronic element and/or the edge of the encapsulation layer, or the recess structure may be disposed correspondingly to the corners of the electronic element and/or the corners of the encapsulation layer.

When the temperature cycling test is performed for the package structure with recess structure, the stress of the conductive balls produced by the difference between the CTEs of the circuit board and the electronic element and/or the circuit board and the encapsulation layer can be reduced, and the stability of the package structure can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package structure, comprising:
a redistribution layer comprising an upper surface and a lower surface opposite to each other, wherein the lower surface of the redistribution layer has at least one first recess;
an electronic element disposed on the upper surface of the redistribution layer;
at least one first conductive ball disposed on the at least one first recess of the redistribution layer, wherein a part of the at least one first conductive ball is filled into the at least one first recess; and
a plurality of second conductive balls disposed on the lower surface of the redistribution layer;
wherein in a direction perpendicular to the lower surface of the redistribution layer, a height of the at least one first conductive ball is larger than a height of each of the second conductive balls.

2. The package structure of claim 1, wherein the electronic element comprises a chip.

3. The package structure of claim 1, wherein the at least one first recess is disposed along an edge of the electronic element in the direction.

4. The package structure of claim 3, wherein the at least one first recess is overlapped with the edge of the electronic element in the direction.

5. The package structure of claim 3, wherein the at least one first recess is not overlapped with the edge of the electronic element in the direction.

6. The package structure of claim 1, wherein the at least one first recess comprises a plurality of first recesses, and each of the first recesses is respectively disposed at a corresponding corner of the electronic element in the direction.

7. The package structure of claim 1, wherein the at least one first recess comprises a plurality of first recesses, and the first recesses are disposed along an edge of the electronic element in the direction.

8. The package structure of claim 7, wherein one of the first recesses are overlapped with the electronic element in the direction.

9. The package structure of claim 7, further comprising an encapsulation layer disposed on the upper surface of the redistribution layer and at least enclosing the electronic element, wherein at least one of the first recesses is overlapped with the encapsulation on the direction.

10. The package structure of claim 1, wherein the redistribution layer comprises a plurality of insulating layers and a plurality of conductive layers, at least one of the insulating layers adjacent to the lower surface has at least one opening, and the at least one opening and one of the conductive layers form the at least one first recess.

11. The package structure of claim 1, further comprising an encapsulation layer disposed on the upper surface of the redistribution layer and at least enclosing the electronic element, wherein the at least one first recess is disposed along an edge of the encapsulation layer on the direction.

12. The package structure of claim 11, further comprising a carrier, wherein the first conductive balls and the second conductive balls are disposed between the redistribution layer and the carrier, and the carrier includes a chip.

13. The package structure of claim 12, wherein a coefficient of thermal expansion of the electronic element is substantially equal to a coefficient of thermal expansion of the carrier.

14. The package structure of claim 1, further comprising:
an encapsulation layer disposed on the upper surface of the redistribution layer and at least enclosing the electronic element, wherein the lower surface of the redistribution layer further comprises at least one second recess overlapped with the encapsulation layer in the direction; and
at least one third conductive ball disposed on the at least one second recess of the redistribution layer, wherein a part of the at least one third conductive ball is filled into the at least one second recess, and a height of the at least one third conductive ball is larger than a height of each of the second conductive balls.

15. The package structure of claim 14, wherein the at least one second recess is disposed along an edge of the encapsulation layer on the direction.

16. The package structure of claim 14, wherein a height of the at least one third conductive ball is equal to a height of the at least one first conductive ball.

17. The package structure of claim 14, wherein a height of the at least one third conductive ball is not equal to a height of the at least one first conductive ball.

18. The package structure of claim 14, wherein the at least one second recess includes a plurality of second recesses, and each of the second recesses is respectively disposed at a corresponding corner of the encapsulation layer on the direction.

19. The package structure of claim 14, further comprising a circuit board, wherein the at least one first conductive ball and the second conductive balls are disposed between the redistribution layer and the circuit board, and a coefficient of thermal expansion of the encapsulation layer is different from a coefficient of thermal expansion of the circuit board.

20. The package structure of claim 1, further comprising a circuit board, wherein the at least one first conductive ball and the second conductive balls are disposed between the redistribution layer and the circuit board, and a coefficient of thermal expansion of the electronic element is different from a coefficient of thermal expansion of the circuit board.
